(19) United States
(12) Patent Application Publication
(10) Pub. No.: US 2008/0119061 A1
(43) Pub. Date: May 22, 2008

(54) SEMICONDUCTOR CHIP HAVING BUMPS OF DIFFERENT HEIGHTS AND SEMICONDUCTOR PACKAGE INCLUDING THE SAME

(75) Inventors: Ji-hwan HWANG, Asan-si (KR); Dong-han KIM, Osan-si (KR); Chul-woo KIM, Cheonan-si (KR); Sang-heui LEE, Cheonan-si (KR); Kwang-jin BAE, Asan-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/758,175

(22) Filed: Jun. 5, 2007

(30) Foreign Application Priority Data
Nov. 21, 2006 (KR) 10-2006-0115430

(51) Int. Cl. H01L 23/48; H05K 1/00

(52) U.S. Cl. 439/55; 257/737; 257/E23.01

(57) ABSTRACT

A semiconductor chip is disclosed and includes a plurality of bond pads disposed on a semiconductor chip, and a plurality of chip bumps of different heights disposed on a corresponding bond pad.

### CROSS-REFERENCE TO RELATED PATENT APPLICATIONS

This application claims the benefit of Korean Patent Application No. 10-2006-0115430, filed on Nov. 21, 2006, the subject matter of which is hereby incorporated by reference.

### BACKGROUND OF THE INVENTION

1. Field of the Invention

The present invention relates to a semiconductor chip and a semiconductor package including the same. More particularly, the invention relates to a semiconductor chip adapted for connection to a circuit board through bumps and a semiconductor package including the semiconductor chip.

2. Description of the Related Art

As contemporary semiconductor chips have become increasing small in size, the constituent bond pads used to connect such semiconductor chips have been implemented with ever finer pitches. As a result of these fine pitch bonds pads, it has become increasingly difficult to connect semiconductor chips with related circuit boards. For example, it is difficult to form printed circuit patterns on the circuit board with correspondingly fine pitches, and misalignment problems and short circuit contacts may result during a subsequent assembly process.

FIG. 1 is a plan view of a conventional semiconductor chip 20 connected to a circuit board 10. FIG. 2 is a cross-sectional view of semiconductor chip 20 taken along line II-II′ of FIG. 1. FIG. 3 is a plan view further illustrating bumps 22A of semiconductor chip 20 in relation to printed circuit patterns 12A formed on circuit board 10.

Referring collectively to FIGS. 1 through 3, circuit board 10 includes a chip area 14 adapted to mount semiconductor chip 20. A plurality of printed circuit patterns 12A to which bumps 22A formed on bond pads 24 of semiconductor chip 20 may be connected are formed on respective inner edge portions within chip area 14. The semiconductor package 40 shown in FIG. 2 comprises a contact structure including bumps 22A formed on bond pads 24 of semiconductor chip 20. Bumps 12A and bond pads 24 are configured in relation to printed circuit patterns 12A formed on circuit board 10 (e.g., the exemplary straight line pattern).

As further illustrated in FIG. 3, as the pitch P1 between adjacent bond pads 24 is reduced so too is the separation distance between corresponding adjacent bond pads 24. At some point, practical considerations such as the risks of misalignment and/or short circuit contacts preclude further reduction in the separation distance between circuit patterns 12A formed on circuit board 10 and related components such as bond pads 24.

FIG. 4 is a plan view of another conventional semiconductor chip 20 adapted for connection to circuit board 10. FIG. 5 is a related cross-sectional view of semiconductor chip 20 taken along line V-V′ of FIG. 4. FIG. 6 is a plan view further illustrating bumps 22B and printed circuit patterns 12B of semiconductor chip 20 and circuit board 10.

Referring collectively to FIGS. 4 through 6, in order to facilitate the formation of printed circuit patterns 12B with a finer pitch than the example of FIGS. 1-3 will allow, a different placement of bumps 22B relative to a staggered configuration of bond pads 24 is made. Semiconductor package 60 may be more safely mounted on circuit board 10 using this arrangement.

Unfortunately, this two dimensional arrangement approach which better facilitates connection between bumps 22B and bond pads 24 of semiconductor chip 20 in relation to printed circuit patterns 12B on circuit board 10, while using available contact area more efficiently, can not be adapted for use in the connection of a semiconductor chip 20 having bumps 22B formed with a fine pitch of 20 μm or less to circuit board 10 in the context of chip on film (COF) packaging.

### SUMMARY OF THE INVENTION

Embodiments of the invention provide a semiconductor chip having bumps formed with different heights. This configuration allows more dense connection patterns between the semiconductor chip and a corresponding circuit board. In effect, embodiments of the invention arrange bumps and corresponding connection components (e.g., bond pads and/or circuit patterns) in three-dimensions to yield more dense connection arrangements.

Embodiments of the invention also provide a semiconductor package including such a semiconductor chip.

In one embodiment, the invention provides a semiconductor chip comprising; a plurality of bond pads disposed on a semiconductor chip, and a plurality of chip bumps of different heights disposed on a corresponding bond pad.

In another embodiment, the invention provides a semiconductor package comprising; a plurality of chip bumps connected to corresponding bond pads on a semiconductor chip, wherein the plurality of chip bumps includes first chip bumps having a first height and second chip bumps having a second height greater than the first height, a circuit board comprising a plurality of first inner leads each having a first lead bump of first height, and a plurality of second inner leads each having a second lead bump of second height less than the first height, wherein electrical connection of the semiconductor chip and the circuit board is made through respective combinations of a first chip bump and a first lead bump and a second chip bump and a second lead bump.

### BRIEF DESCRIPTION OF THE DRAWINGS

Embodiments of the invention will be described with reference to the attached drawings in which:

FIG. 1 is a plan view illustrating a semiconductor chip connected to a circuit board according to the conventional art;

FIG. 2 is a cross-sectional view illustrating the semiconductor chip connected to the circuit board according to the conventional art;

FIG. 3 is a plan view illustrating bumps and printed circuit patterns on the semiconductor chip and the circuit board according to the conventional art;

FIG. 4 is a plan view of a semiconductor chip connected to a circuit board according to other conventional art;

FIG. 5 is a cross-sectional view of the semiconductor chip connected to the circuit board according to the other conventional art;

FIG. 6 is a plan view of bumps and printed circuit patterns on the semiconductor chip and the circuit board according to the conventional art;

FIG. 7 is a plan view illustrating a film used in a conventional chip on film (COF) package;

FIG. 8 is a cross-sectional view illustrating the semiconductor chip bonded to the circuit board in a COF package or a flip chip package according to an embodiment of the present invention;

FIG. 9 is a plan view illustrating positions of bumps on the semiconductor chip and the circuit board, according to an embodiment of the present invention;

FIG. 10 is a plan view illustrating the semiconductor chip connected to the circuit board according to an embodiment of the present invention;

FIG. 11 is a cross-sectional view illustrating an example of bumps of the semiconductor chip, according to another embodiment of the present invention; and

FIGS. 12 and 13 are cross-sectional views illustrating examples of bumps of the semiconductor chip, according to embodiments of the present invention.

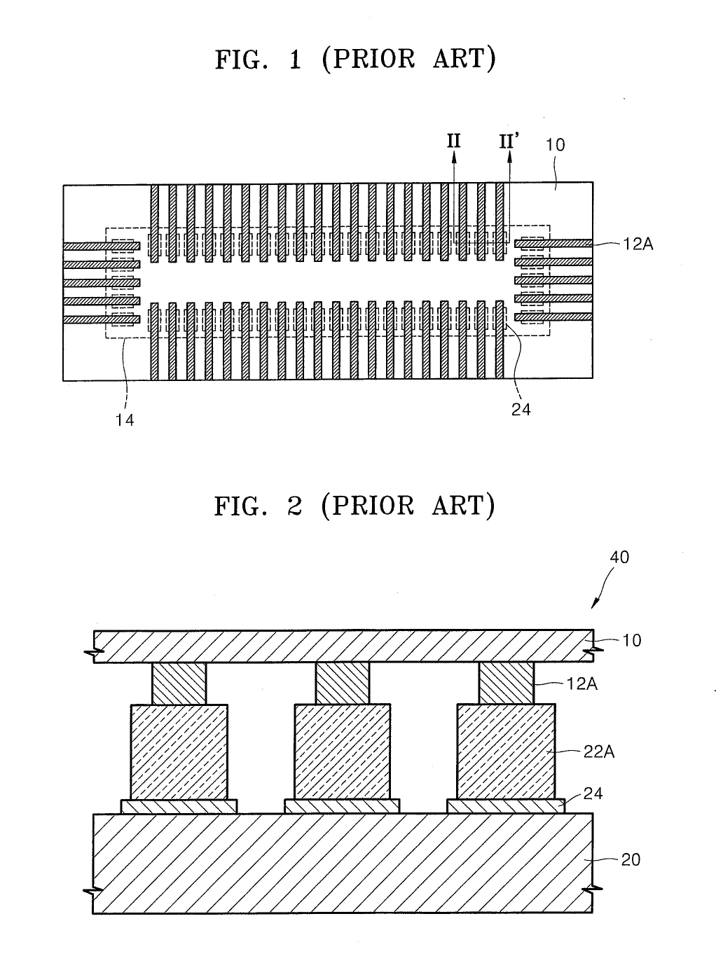

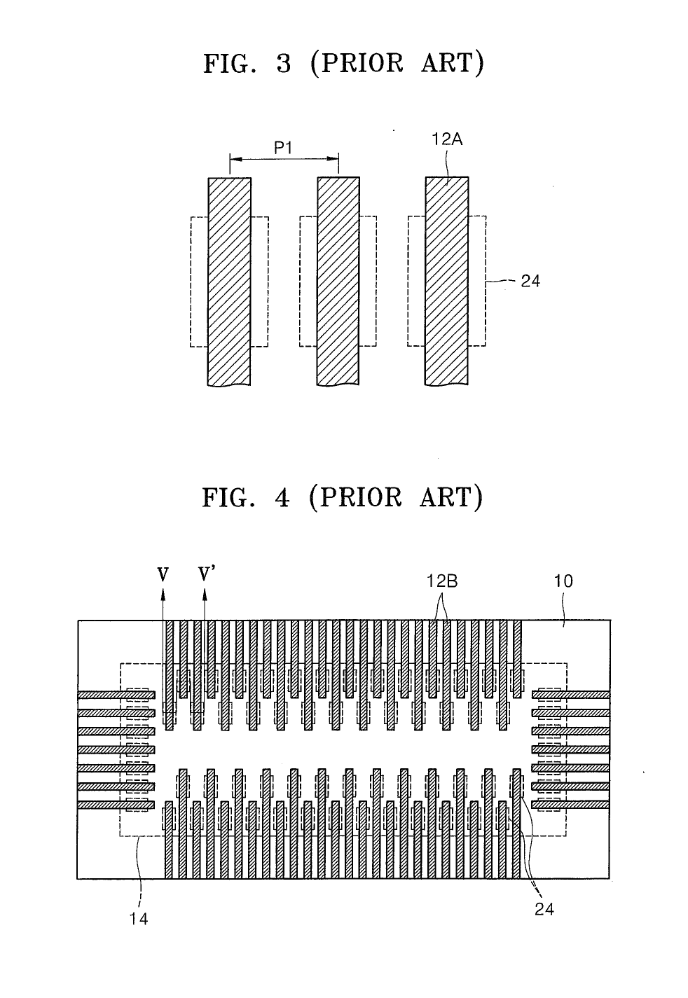

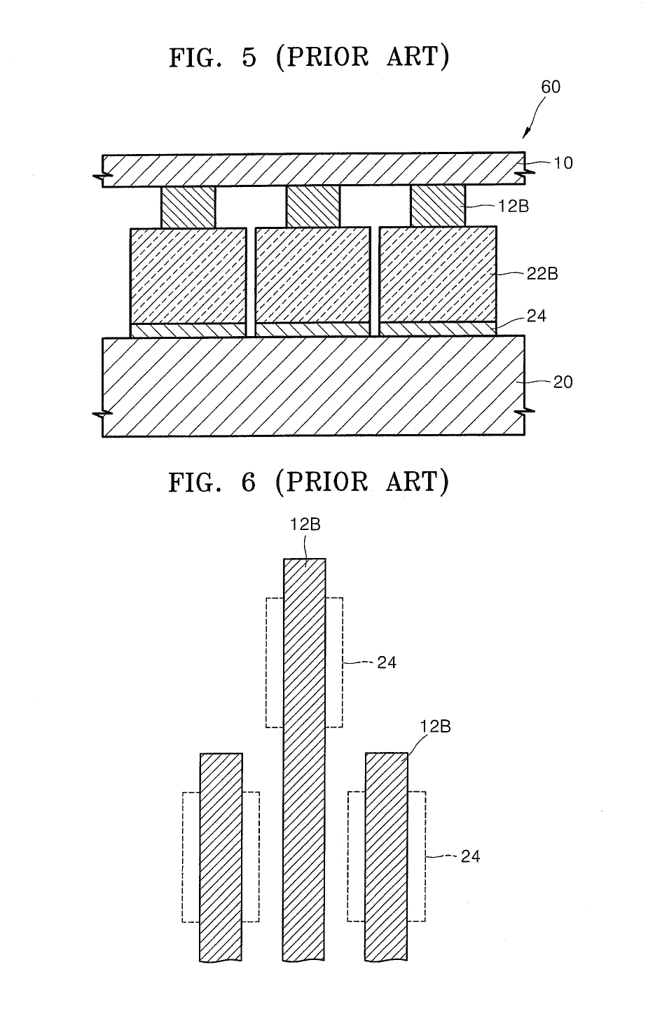

### DESCRIPTION OF EMBODIMENTS

Embodiments of the invention will now be described in some additional detail with reference to the accompanying drawings. The invention may, however, be embodied in many different forms and should not be construed as being limited to only the illustrated embodiments. Rather, the embodiments are provided as teaching examples.

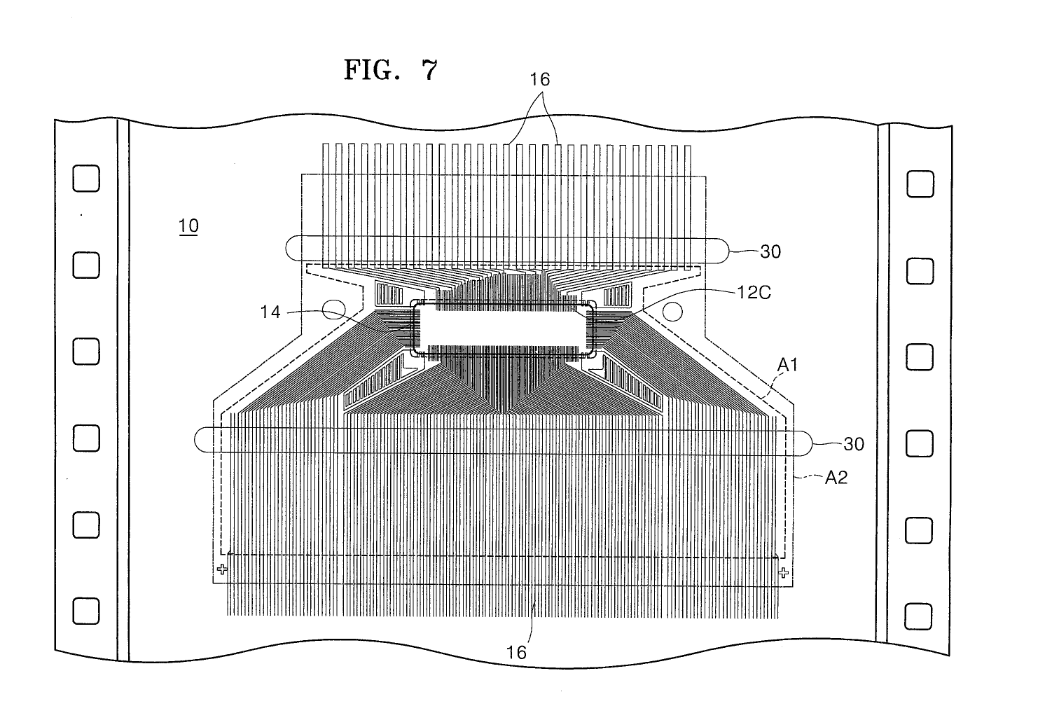

FIG. 7 is a plan view of a film 10 adapted to mount one or more semiconductor chips using conventional chip on film (COF) packaging techniques. Film 10 of FIG. 7 is shown in a state where it is prepared to receive a semiconductor chip. Film 10 is illustrated in the form of a conventional COF package, film 10 being formed from polyimide or some similar material having a superior thermal expansion coefficient or great durability. However, the scope of the invention is not limited to COF packages, but may be more broadly applied across a range of semiconductor packaging. A chip mounting area 14 on film 10 is provided to receive one or more semiconductor chips. Printed circuit patterns 12C extend into (or to) chip mounting area 14 and function as inner leads, and may be densely formed around the periphery of chip mounting area 14.

In one embodiment of the invention, a slit 30 is provided in film 10 to allow the polyimide material forming film 10 to bend or curve sufficiently.

As shown in FIG. 7, the printed circuit patterns 12C extend outward from chip mounting area 14 and serve as outer leads 16. Outer leads 16 may be covered in a first area A1 with a solder resist which prevents printed circuit patterns 12C from being damaged or electrically shorted during subsequent processing.

The foregoing components (e.g., mounting are 14, inner leads and outer leads of printed circuit patterns 12C, etc.) may be removed from the polyimide substrate by cutting along line A2. This cutting process is commonly performed only after completion of package level electrical testing for the individual COF package.

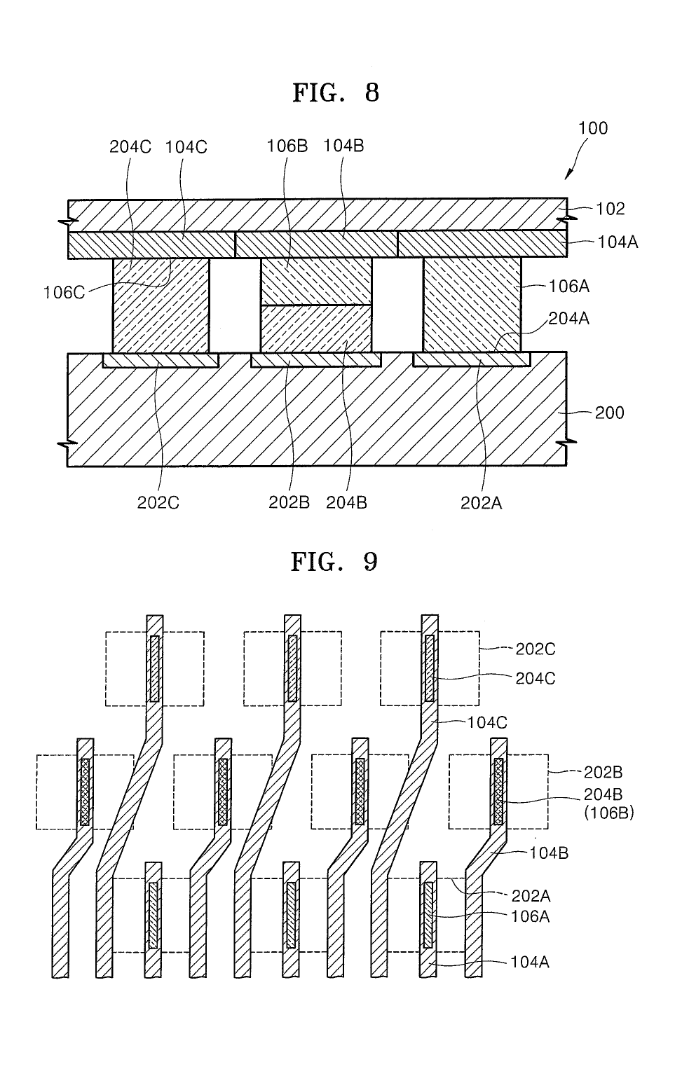

FIG. 8 is a cross-sectional view illustrating the semiconductor chip bonded to the circuit board in a COF package or a flip chip package.

Referring to FIG. 8, conventional bond pads 202A, 202B, and 202C are formed on a semiconductor chip 200 in three rows. In the illustrated embodiment, chip bumps 204A, 204B and 204C having different heights are respectively formed on bond pads 202A, 202B, and 202C.

In the illustrated example, first chip bumps 204A connected with a first row of bond pads 202A have a first height of zero. Second chip bumps 204B connected to a second row of bond pads 202B have a second height greater than zero. Third chip bumps 204C connected to a third row of bond pads 202C have a third height greater than the second height. This arrangement of chip bumps having different heights within the context of a row-wise arrangement of bond pads allows three dimensional connection of semiconductor chip 200 with circuit board 102 even where the inner leads formed on the circuit board are separated by a very small pitch.

In the illustrated embodiment, bumps 204A, 204B, and 204C and corresponding bond pads 202A, 202B, and 202C are formed with the same height in each connection row. However, this need not always be the case and individual row-wise height variations may work in some embodiments.

In one embodiment of the invention, chip bumps 204A, 204B and 204C are formed from Au.

The connected inner lead portions of printed circuit patterns 104A, 104B, and 104C are presented to the connection areas in a staggered offset manner. That is, a collection of first inner leads 104A terminates at a first row of bonding pads 202A via corresponding first lead bumps 106A having a first height. A collection of second inner leads 104B extends in a laterally offset manner beyond the termination point of first inner leads 104A and terminates at a second row of bonding pads 202B via corresponding second lead bumps 106B having a second first height. A collection of third inner leads 104C extends in a laterally offset manner beyond the termination point of second inner leads 104B and terminates at a third row of bonding pads 202C via corresponding third lead bumps 106C having a third height.

In the illustrated example of FIG. 8, circuit board 102 may be a rigid type substrate formed of a resin such as FR4 or BT, or a flexible type substrate formed of polyimide. In combination, the lead bumps 106A, 106B and 106C formed on respective first, second and third printed circuit patterns 104A, 104B and 104C and the chip bumps 204A, 204B and 204C formed on respective bond pads 202A, 202B and 202C of semiconductor chip 200 form connections of similar combined heights where the combined height value is defined as the separation distance between opposing surface of semiconductor 200 and printed circuit board 102.

In effect the corresponding connection between chip bumps and lead bumps of variable height allows Z-plane separation as well as Y-plane separation of narrowly pitched inner leads as a remedy for inner lead crowding across the X-plane and the attendant connection problems. This description assumes relative to the illustrated embodiments of FIGS. 8 and 9, that the Z-plane is oriented vertically from semiconductor chip 200 to printed circuit 102 in FIG. 8, that the Y plane is oriented in the upward extension of inner leads in FIG. 9, and that the X-plane is oriented laterally across both FIGS. 8 and 9. Such geometrically descriptive terms are, of course, entirely arbitrary and merely serve to distinguish selected examples of three plane inner lead separation for connection. However, this type of three plane inner lead separation and connection allows a semiconductor chip 200 to be effectively and reliably connected to inner leads separated by a pitch of 20 μm or less.

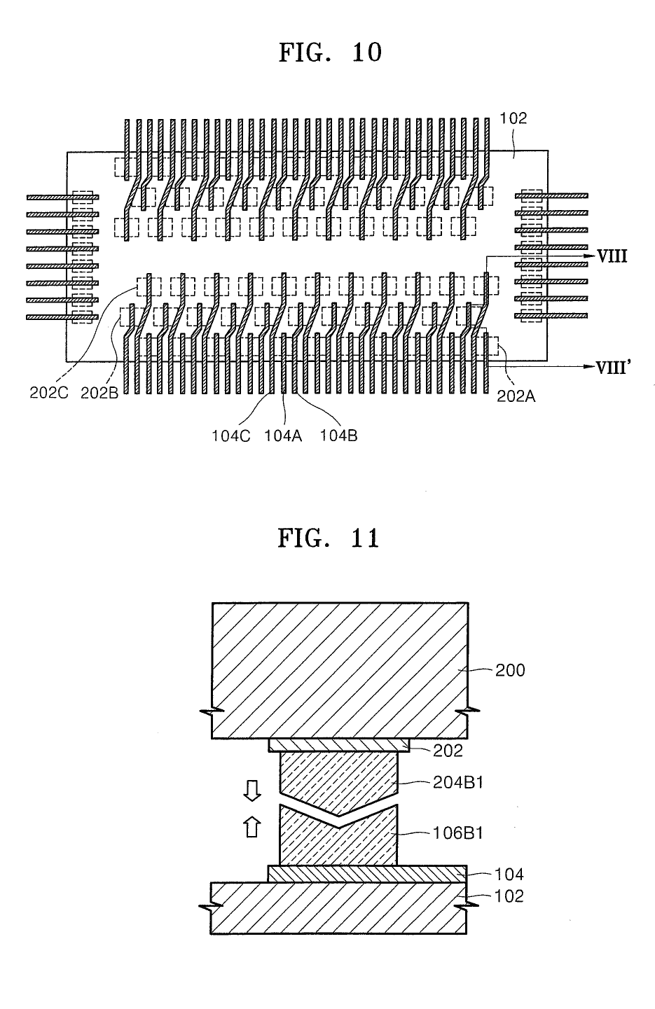

The staggered offset arrangement of FIG. 9 is further illustrated in the plan view of FIG. 10.

Referring to FIGS. 9 and 10, the rows of bond pads associated with semiconductor chip 200 may be arranged in an offset (or zigzag) pattern to better facilitate the connection of inner leads 104A, 104B and 104C. In the illustrated example of FIG. 10, the first and third bond pad rows 202A and 202C are arranged in a columnar order. In contrast, the intervening second bond pad row 202B is offset in its columnar position relative to this orientation. Of further note, the illustrated examples only show printed circuit patterns and corresponding connection to one surface of semiconductor chip 200. Those of ordinary skill in the art will recognize that that the three-dimensional inner lead separation and connection arrangement of the present invention may be applied to semiconductor chips having connection on both upper and lower surfaces, as well as the connection of additional inner leads oriented to lateral ends of a mounted semiconductor chip.

Semiconductor package 100 contemplated in FIG. 7 may use COF, TCP or flip chip packaging techniques while also implementing the three dimensional inner lead separation and connection scheme using chip and/or lead bumps of varying height.

FIG. 11 is a cross-sectional view of an embodiment of the invention further characterized by the provision of structurally specific bumps.

Referring to FIG. 11, the corresponding lead bump 106B1 and chip bump 204B1 terminate with non-planar surfaces designed to mate in a more secure manner. Here, the respective bump heights may vary for chip bump 204B1 connected to bond pad 202 and lead bump 106B1 connected to inner lead 104. Such non-planar (or irregular) bump structures facilitate the mating of corresponding bumps despite the presence of small misalignments. In addition to the V-shaped irregular structures illustrated in FIG. 11, other irregular structures might be used, such as W-shaped, concave/convex-shapes, block-shaped, etc.

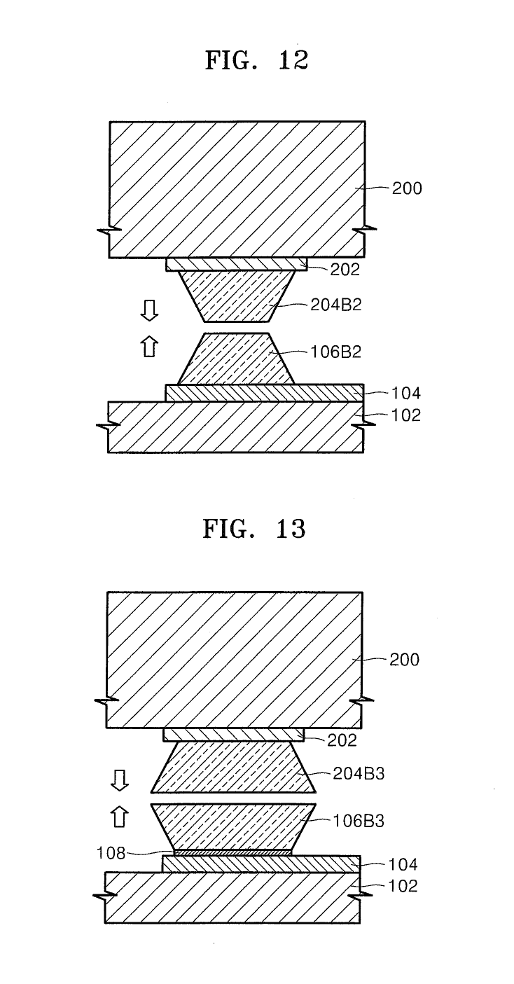

FIGS. 12 and 13 are cross-sectional views illustrating other examples of the bumps according to embodiments of the present invention.

Referring to FIG. 12, mating lead and chip bumps 204B2 and 106B2 are formed with angular shapes that narrow as they extend from their respective connecting surfaces. In addition, as shown in FIG. 13, mating lead and chip bumps 204B3 and 106B3 are formed with angular shapes that broaden as they extend from their respective connecting surfaces.

In the foregoing examples, printed circuit pattern 104 may be formed from copper or a similar conductive material.

Lead bumps 106 formed on printed circuit pattern 104 may be formed from gold with an intervening nickel layer 108 formed between printed circuit pattern 104 and bump 106.

While the present invention has been particularly shown and described with reference to exemplary embodiments thereof, it will be understood by one of ordinary skill in the art that various changes in form and details may be made therein without departing from the scope of the invention as defined by the following claims.

What is claimed is:

1. A semiconductor chip comprising:
a plurality of bond pads disposed on a semiconductor chip; and
a plurality of chip bumps of different heights disposed on a corresponding bond pad.

2. The semiconductor chip of claim 1, wherein the plurality of bond pads are arranged in a plurality of rows on the semiconductor chip.

3. The semiconductor chip of claim 2, wherein each one of the plurality of chip bumps varies in respective height according to the row of its corresponding bond pad.

4. The semiconductor chip of claim 3, wherein adjacent rows in the plurality of bond pad rows are arranged with an offset.

5. The semiconductor chip of claim 4, wherein the plurality of bond pad rows are arranged in a zigzag pattern and are connected to a collection of inner leads arranged in a staggered offset pattern.

6. The semiconductor chip of claim 1, wherein the plurality of bond pads are arranged in a first row, a second row, and third row on the semiconductor chip; and
the plurality of chip bumps comprises;
first chip bumps having a first height and being respectively connected to a bond pad in the first row of bond pads;
second chip bumps having a second height greater than the first height and being respectively connected to a bond pad in the second row of bond pads;
third chip bumps having a third height greater than the second height and being respectively connected to a bond pad in the third row of bond pads.

7. The semiconductor chip of claim 6, wherein the first height for the first chip bumps is zero.

8. The semiconductor chip of claim 6, further comprising a chip mounting area receiving a collection of inner leads;
wherein the first, second, and third bond pad rows are arranged in an adjacent row offset pattern beginning with the first bond pad row disposed proximate an edge of the chip mounting area, the second bond pad row disposed behind the first bond pad row further away from the edge of the chip mounting area, and the third bond pad row disposed behind the second bond pad row still further away from the edge of the chip mounting area.

9. The semiconductor chip of claim 6, wherein at least the second and third chip bumps respectively terminate in an irregularly shaped end portion.

10. A semiconductor package comprising:
a plurality of chip bumps connected to corresponding bond pads on a semiconductor chip, wherein the plurality of chip bumps includes first chip bumps having a first height and second chip bumps having a second height greater than the first height;
a circuit board comprising a plurality of first inner leads each having a first lead bump of first height, and a plurality of second inner leads each having a second lead bump of second height less than the first height;
wherein electrical connection of the semiconductor chip and the circuit board is made through respective combinations of a first chip bump and a first lead bump and a second chip bump and a second lead bump.

11. The semiconductor package of claim 10, wherein the semiconductor package is one selected from the group consisting of a chip on film (COF) and a tape carrier package (TCP).

12. The semiconductor package of claim 10, wherein the semiconductor package is a flip chip package.

13. The semiconductor package of claim 10, wherein the bond pads of the semiconductor chip are formed in a plurality of rows.

14. The semiconductor package of claim 13, wherein each first chip bump is respectively connected to a bond pad in a first row of bond pads and each second chip bump is respectively connected to a bond pad in a second row of bond pads.

15. The semiconductor package of claim 10, wherein each lead bump extends from an inner lead in an angular manner to terminate in an end portion wider than a portion connecting the inner lead, and each chip bump extends from a bond pad in an angular manner to terminate in an end portion wider than a portion connecting the bond pad.

16. The semiconductor package of claim 10, wherein each lead bump extends from an inner lead in an angular manner to terminate in an end portion narrower than a portion connecting the inner lead, and each chip bump extends from a bond pad in an angular manner to terminate in an end portion narrower than a portion connecting the bond pad.

17. The semiconductor package of claim 10, wherein each lead bump comprises; a nickel (Ni) layer formed between an inner lead formed from copper (Cu), and a gold (Au) layer formed on the Ni layer.

18. The semiconductor package of claim 10, wherein the bond pads of the semiconductor chip are arranged in first, second and third rows;
the plurality of chip bumps further comprises third chip bumps having a third height greater than the second height and the circuit board further comprises a plurality of third inner leads each having a third lead bump of third height greater than the second height; and
electrical connection of the semiconductor chip and the circuit board is additionally made through respective combinations of a third chip bump and a third lead bump.

19. The semiconductor package of claim 18, wherein each first lead bump makes connection to a corresponding first chip bump associated with a bond pad in the first row of bond pads;
each second lead bump makes connection to a corresponding second chip bump associated with a bond pad in the second row of bond pads; and
each third lead bump makes connection to a corresponding third chip bump associated with a bond pad in the third row of bond pads.

20. The semiconductor package of claim 19, wherein at least each second and third chip bump and each first and second lead bump terminates in an irregular end portion.
